(19) United States
(12) Patent Application Publication
(10) Pub. No.: US 2026/0197580 A1
(43) Pub. Date: Jul. 9, 2026

(54) ADAPTIVE CURRENT LIMITER FOR CAPACITIVE LOADS

(71) Applicant: Nuvoton Technology Corporation, Hsinchu (TW)

(72) Inventors: Powen Ru, Gaithersburg, MD (US); Peter Dinh, San Jose, CA (US); Xiaqing Ren, Santa Clara, CA (US); Tawei Yang, Fremont, CA (US)

(21) Appl. No.: 19/012,749

(22) Filed: Jan. 7, 2025

(51) Int. Cl. H04R 3/00; H03F 3/20; H04R 3/04; H04R 17/00

(52) U.S. Cl. CPC H04R 3/007; H04R 3/04; H04R 17/00; H03F 3/20; H03F 2200/03

(57) ABSTRACT

Adaptive current limiters for capacitive loads (and associated systems, devices, and methods) are disclosed herein. In one embodiment, a signal emitting system includes a signal processing unit, an amplifier, and an emitter. The signal processing unit can determine a delta limit based on (i) system parameters and (ii) a representative magnitude corresponding to a sample of a source signal, one or more samples of a conditioned signal, or a combination thereof. The signal processing unit can further determine a ratio of (i) the delta limit to (ii) a difference between a sample of the source signal and a previous sample of the source signal, and apply a lowpass filter to the source signal to obtain a filtered signal, with filter coefficients based on the ratio. The amplifier can generate an amplified signal based on the filtered signal, and the emitter can emit an output signal based on the amplified signal.

### TECHNICAL FIELD

This disclosure relates generally to signal emitting systems. For example, several embodiments of the present technology are generally directed to signal conditioning modules for efficiently controlling current and power consumption in signal emitting systems with capacitive loads.

### BACKGROUND

Capacitive loads, such as piezoelectric speakers, are widely used in various electronic devices for sound generation. These loads are characterized by their unique electrical properties, particularly their impedance characteristics that vary with frequency. As the frequency of the input signal increases, the impedance of capacitive loads typically decreases, leading to potential challenges in driving these loads efficiently and safely. One such challenge is that signals at higher frequencies can cause current overloading.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 illustrates impedance or admittance characteristic plots for piezoelectric speakers across different frequencies.

FIG. 2 is a block diagram of a signal emitting system configured in accordance with various embodiments of the present technology.

FIG. 3 is a block diagram of a digital signal processing unit configured in accordance with various embodiments of the present technology.

FIG. 4 is a plot showing delta limit curves for different voltage and power ratings in accordance with various embodiments of the present technology.

FIG. 5 is a plot showing frequency responses of a first-order finite impulse response low-pass filter in accordance with various embodiments of the present technology.

FIG. 6 is a plot showing frequency responses of a first-order infinite impulse response low-pass filter configured in accordance with various embodiments of the present technology.

FIG. 7 is a flow diagram illustrating a method of processing a signal for emission via a capacitive load in accordance with various embodiments of the present technology.

FIG. 8 illustrates a set of three vertically aligned plots that show different aspects of signal processing for a capacitive load in accordance with various embodiments of the present technology.

FIG. 9 illustrates (i) a first spectrogram of an audio signal processed using a dynamic conditioning filter in accordance with various embodiment of the present technology and (ii) a second spectrogram of the same audio signal processed using a fixed bandlimiter.

### DETAILED DESCRIPTION

The present disclosure relates to adaptive current limiters for capacitive loads in signal emitting systems. For example, several embodiments of the present technology are directed to signal emitting systems with capacitive loads (e.g., piezo speakers), which may be characterized by decreasing impedance as frequency increases. This characteristic may pose challenges for driving capacitive loads efficiently and safely, particularly at higher frequencies where current overloading may occur.

Thus, to address these challenges, several embodiments of the present technology include signal drivers with signal conditioning modules that are configured to dynamically condition source signals to maintain current in the signal emitting systems within desirable limits. This may be accomplished by accurately estimating current, efficiently determining coefficients of a lowpass filter, adaptively applying the filter to the source signals, and gatekeeping each signal sample. In some embodiments, the signal conditioning modules include dynamic conditioning filters, delta control blocks, and limit/coefficient generators. The limit/coefficient generators can be configured to set, based at least in part on a plurality of system parameters (e.g., voltage, current, and power ratings), coefficients for the dynamic conditioning filters and delta limits for the delta control blocks. As a result, the present technology is expected to offer a balance between signal fidelity, current limiting, and computational efficiency when driving capacitive loads.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

### A. OVERVIEW

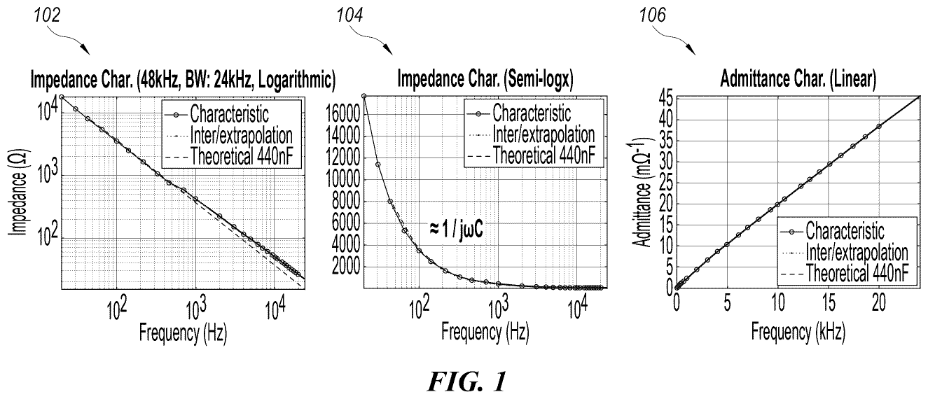

Many signal emitting systems utilize capacitive loads, such as piezoelectric speakers, which are characterized by decreasing impedance as frequency increases. For example, FIG. 1 illustrates two impedance characteristic plots 102, 104 and one admittance characteristic plot 106 for piezoelectric speakers across different frequencies. Plot 102 shows the impedance response on a logarithmic scale, with impedance decreasing as frequency increases. Plot 104 shows the impedance response on a semi-logarithmic scale, again demonstrating how impedance decreases as frequency increases. Plot 106 displays the admittance response on a linear scale, illustrating how admittance increases as frequency increases. Such impedance and admittance characteristics of capacitive loads pose challenges for driving these loads efficiently and safely, particularly at higher frequencies where current overloading can occur.

One approach to addressing this issue includes using series resistors as current limiters. This approach, however, introduces (a) undesirable heat dissipation and (b) constant signal attenuation at higher frequencies, resulting in reduced signal fidelity and undesirable power dissipation. Another approach includes utilizing fixed lowpass filters to attenuate high-frequency content. While this approach avoids undesirable heat dissipation, it still introduces constant attenuation at high frequency regions, compromising signal quality and making such an approach unsuitable for high-fidelity reproduction. Still another approach includes (i) estimating current in the frequency domain, (ii) dynamically determining a filter with a desired cutoff frequency and roll-off slope, (iii) applying the filter to signals in the frequency domain, and (iv) reconstructing the signal back to the time domain. Such an approach typically requires buffering samples and performing complex mathematical operations (e.g., Fast Fourier Transforms (FFTs) and iterative algorithms for polynomial root finding). Such an approach therefore introduces significant processing delays and requires complex hardware implementations, making it less suitable for applications where low latency and reduced computational complexity are crucial.

By contrast, several embodiments of the present technology are directed to signal emitting systems with capacitive loads (e.g., piezo speakers) that are driven by signal drivers implementing signal conditioning modules configured to dynamically condition source signals. More specifically, signal conditioning modules configured in accordance with various embodiments of the present technology can include dynamic conditioning filters, delta control blocks, and limit/coefficient generators. The limit/coefficient generators can set, based on a plurality of system parameters (e.g., voltage, current, and power ratings), (i) coefficients for the dynamic conditioning filters and (ii) delta limits for the delta control blocks. In operation, the signal conditioning modules can keep current consumption in the signal emitting systems under desirable limits by accurately estimating current, efficiently determining coefficients of a lowpass filter, adaptively applying the lowpass filter to source signals, and gatekeeping each signal sample.

The present technology is therefore expected to offer several advantages over the various other approaches discussed above for controlling current consumption when driving capacitive loads. For example, unlike series resistors that introduce constant attenuation and heat dissipation, or fixed lowpass filters that compromise signal quality, the present technology dynamically adapts to signal characteristics to control current consumption. Such an adaptive approach of the present technology allows for maintaining signal fidelity when possible, while still preventing current overloading and undesirable heat dissipation. Furthermore, in contrast with approaches that require complex frequency domain operations, the present technology operates in the time domain. As a result, the present technology does not require signal buffering or utilizing complex mathematical operations. Instead, the present technology utilizes efficient, low-complexity algorithms. As such, the present technology is expected to achieve low latency and reduced computational complexity, and is further expected to enable use of relatively simple hardware implementations. In other words, the present technology is expected to offer a balance between signal fidelity, current limiting, and computational efficiency when driving capacitive loads.

### B. SELECTED EMBODIMENTS OF ADAPTIVE CURRENT LIMITERS FOR CAPACITIVE LOADS, AND ASSOCIATED SYSTEMS, DEVICES, AND METHODS

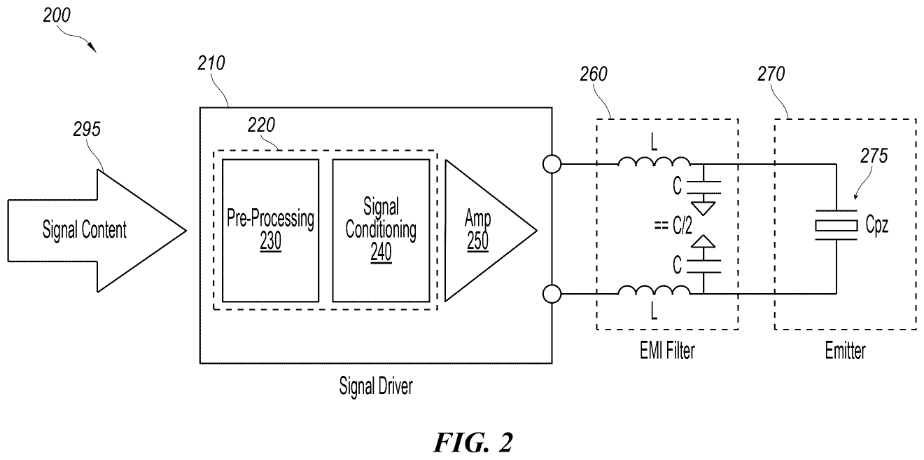

FIG. 2 is a block diagram illustrating a signal emitting system 200 configured in accordance with various embodiments of the present technology. As shown, the signal emitting system 200 includes a signal driver 210 and an emitter 270. The signal driver 210 includes a digital signal processing unit 220 and an amplifier 250. The digital signal processing unit 220 contains a pre-processing module 230 and a signal conditioning module 240. In some embodiments, the signal emitting system 200 may further include an electromagnetic interference (EMI) filter 260. In other embodiments, the EMI filter 260 can be omitted.

The signal emitting system 200 is configured to receive signal content 295 as input. In some embodiments, the signal content 295 may include audio signals. As a specific example, the signal content 295 may include audio signals with an audio bandwidth of approximately 60 Hz to 20 kHz, a sample rate of 44.1 kHz or 48 kHz, and a bit depth of 16, 24, or 32 bits. The signal content 295 may originate from various sources, such as a storage device or a streaming device.

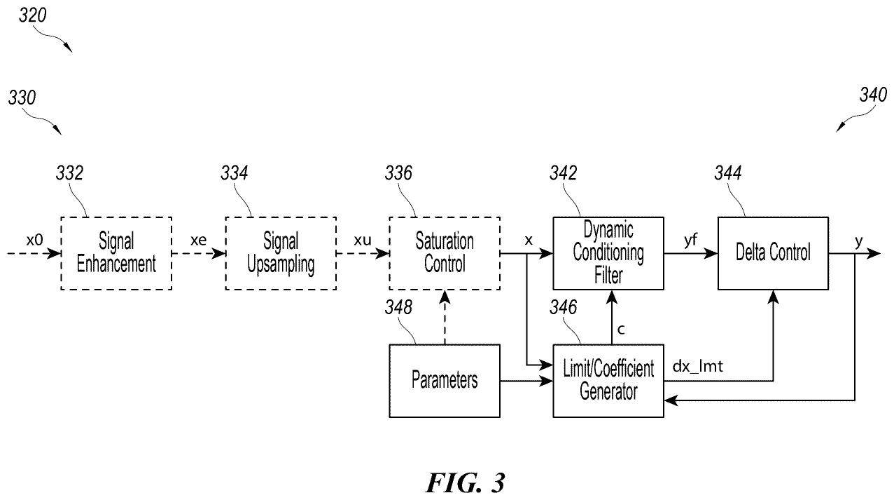

The digital signal processing unit 220 of the signal driver 210 processes the received signal content 295. In some embodiments, the pre-processing module 230 of the digital signal processing unit 220 performs initial signal processing operations. Such operations can include audio enhancement techniques, bass boost, equalization (EQ), upsampling, and/or saturation control. Following the pre-processing module 230, the signal conditioning module 240 of the digital signal processing unit 220 dynamically modifies/conditions the signal content to generate a conditioned signal. As described in greater detail below with reference to FIG. 3, the signal conditioning module 240 is configured to manipulate the signal content in a manner that reduces or controls current consumption in the system 200.

After digital signal processing, the amplifier 250 of the signal driver 210 amplifies the conditioned signal output from the signal conditioning module 240. In some embodiments, the amplifier 250 is a class D or class AB amplifier with specified voltage, current, and power (VIP) ratings. The amplified signal output from the amplifier 250 is then either provided to the EMI filter 260 (when present) or to the emitter 270.

The EMI filter 260, when included, can be designed to reduce, minimize, or eliminate electromagnetic interference (e.g., noise). In some embodiments, the EMI filter 260 includes an LC filter comprising one or more inductors and one or more capacitors arranged in a specific configuration to filter out unwanted frequencies/noise. In the illustrated embodiment, each inductor of the EMI filter 260 has an inductance L, and each capacitor of the EMI filter 260 includes a capacitance C. The inductors in the EMI filter 260 may have specified current ratings. Additionally, or alternatively, the EMI filter 260 may include a ferrite-bead filter.

The output of the EMI filter 260 (when present), or the amplified signal directly from the amplifier 250 (when the EMI filter 260 is omitted), may be provided to the emitter 270. In turn, the emitter 270 is configured to emit an output signal. As shown, the emitter 270 includes a capacitive load 275. In some embodiments, the capacitive load 275 includes a piezoelectric speaker, which may have specified voltage and power ratings. The capacitive load 275 is represented by a capacitor Cpz in FIG. 2. In some embodiments, the emitter 270 can exhibit increasing admittance (and/or decreasing impedance) as frequency of the amplified signal increases.

As discussed in greater detail below, the signal emitting system 200 is designed to process and emit signals while managing electromagnetic interference and/or accommodating the impedance/admittance characteristics of the capacitive load 275. More specifically, the digital signal processing unit 220 of the signal driver 210—in particular, the signal conditioning module 240—enables the signal emitting system 200 to effectively handle signal content across a range of frequencies and amplitudes, while addressing challenges associated with driving capacitive loads, particularly at higher frequencies where current overloading can occur.

FIG. 3 is a block diagram illustrating a digital signal processing unit 320 configured in accordance with various embodiments of the present technology. For example, the digital signal processing unit 320 can be a digital signal processor for conditioning signals for a capacitive load. The digital signal processing unit 320 can be an example of the digital signal processing unit 220 of FIG. 2, or of other digital signal processing units configured in accordance with various embodiments of the present technology.

As shown, the digital signal processing unit 320 includes a pre-processing module 330 and a signal conditioning module 340. Components of the pre-processing module 330 are illustrated using dashed/broken boxes and corresponding arrows in FIG. 3 while components of the signal conditioning module 340 are illustrated using solid boxes and corresponding arrows. In the illustrated embodiment, the pre-processing module 330 includes a signal enhancement block 332, a signal upsampling block 334, and a saturation control block 336. The signal conditioning module 340 includes a dynamic conditioning filter 342, a delta control block 344, a limit/coefficient generator 346, and a system parameters block 348. As discussed in greater detail below, the components of the signal conditioning module 340 are configured to manipulate a source signal x to reduce current consumption of a corresponding signal emitting system (e.g., the signal emitting system 200 of FIG. 2).

Referring first to the pre-processing module 330, the signal enhancement block 332 receives signal content x0 and outputs enhanced signal content xe. In some embodiments, the signal enhancement block 332 performs audio enhancement techniques on the input signal content x0. These techniques may include bass boost, equalization (EQ), or other audio processing operations to improve the quality or characteristics of the signal content x0.

In turn, the signal upsampling block 334 receives the enhanced signal content xe from the signal enhancement block 332 and increases the sample rate to produce upsampled signal content xu. In some embodiments, the signal upsampling block 334 upsamples the signal to at least 128 kHz. This higher sampling rate is expected to enable more accurate current estimation in subsequent processing stages. As a specific example, the signal upsampling block 334 can quadruple the sample rate of enhanced signal content xe, such as from 48 kHz to 192 kHz. Upsampling performed by the signal upsampling block 334 can ensure that a maximum gradient of the upsampled signal content xu is greater than or equal to that of the enhanced signal content xe.

The saturation control block 336 may receive the upsampled signal xu from the signal upsampling block 334 and use it to generate a source signal x. In some embodiments, the saturation control block 336 limits (e.g., compresses) the upsampled content xu to a valid dynamic range (e.g.,-3 dB) based on system parameters received from the system parameters block 348. For example, over-voltage observed in the upsampled signal xu at the saturation control block 336 can be due to over-feeding, enhancement performed by the signal enhancement block 332, and/or upsampling performed by the signal upsampling block 334. Continuing with this example, the saturation control block 336 can limit an output voltage of the source signal x to less than or equal to a supply voltage (e.g., of an amplifier, such as the amplifier 250 of FIG. 2) while maintaining the fidelity of lower-amplitude signal content. As another example, the saturation control block 336 can limit the output voltage of the source signal x to less than or equal to a voltage limit Vx (e.g., a minimum of a supply voltage of an amplifier (e.g., the amplifier 250 of FIG. 2), a voltage rating of a capacitive load (e.g., the capacitive load 275 of FIG. 2), and a voltage rating of capacitors of an LC filter (e.g., of the EMI filter 260 of FIG. 2)), while maintaining the fidelity of lower-amplitude signal content. As a specific example, the saturation control block 336 can limit the output voltage of the source signal x to less than or equal to 12V. In some embodiments, the valid dynamic range can be a ratio of the voltage limit Vx to a full-scale voltage Vf. As a specific example, assuming the voltage limit Vx is 12V and the full-scale voltage Vf is 15.4V, the valid dynamic range based on these system parameters can be ±12V/15.4V, or ±0.779 (e.g., −2.16 dB). As shown in FIG. 3, the saturation control block 336 outputs the source signal x to the dynamic conditioning filter 342 and the limit/coefficient generator 346 of the signal conditioning module 340.

Referring now to the signal conditioning module 340, the system parameters block 348 contains various ratings and specifications for a signal emitting system (e.g., the signal emitting system 200 of FIG. 2) that corresponds to the digital signal processing unit 320. The ratings and specifications can depend on components of the signal emitting system. For example, the ratings and specifications can depend on ratings and specifications for components placed in series with an emitter (e.g., the emitter 270) of the signal emitting system. The ratings and specifications contained by the systems parameters block 348 can include voltage, current, power (VIP) ratings, saturation currents, sample rates, load capacitance, etc. For example, the system parameters can include a full-scale voltage Vf (e.g., 15.4V), a voltage limit Vx, a current limit Ix, a power limit Px, a combined (or load) capacitance C, a saturation current(s), a sample rate Fs (e.g., 192 kHz), among other parameters.

As discussed above, the voltage limit Vx can be equivalent to a supply voltage (e.g., 12V), or equivalent to a minimum of (i) a supply voltage of an amplifier (e.g., the amplifier 250 of FIG. 2), (ii) a voltage rating of a capacitive load (e.g., the capacitive load 275 of FIG. 2), and (iii) a voltage rating of capacitors of an LC filter (e.g., the LC filter of the EMI filter 260 of FIG. 2). As a specific example, the voltage limit Vx can be 12V.

The current limit Ix can be less than or equal to a minimum of the current ratings and the saturation currents of any component placed in series with an emitter (e.g., the emitter 270 of FIG. 2) of a corresponding signal emitting system. For example, the current limit Ix can be equivalent to a minimum of the current rating and saturation current of (a) an amplifier (e.g., the amplifier 250 of FIG. 2), (b) an inductor (e.g., of the EMI filter 260 of FIG. 2), and (c) a capacitive load (e.g., the capacitive load 275 of FIG. 2). As a specific example, the current limit Ix can be 3 A.

Similarly, the power limit Px can be equivalent to a minimum of the power rating of an amplifier (e.g., the amplifier 250 of FIG. 2) and the power rating of a signal emitter (e.g., the emitter 270) of a corresponding signal emitting system. The load capacitance C can be equivalent to the capacitance of a capacitive load (e.g., the capacitive load 275 of FIG. 2), such as when a corresponding signal emitting system omits an EMI filter (e.g., the EMI filter 260 of FIG. 2). Alternatively, the load capacitance C can be equivalent to a combined capacitance. For example, the load capacitance C can be equivalent to a combination of (i) the capacitance of a capacitive load (e.g., the capacitive load 275 of FIG. 2) and (ii) the capacitance of an LC filter (e.g., of the EMI filter 260 of FIG. 2), such as in embodiments the include an EMI filter that employs an LC filter.

As shown in FIG. 3, the system parameters block 348 is configured to provide system parameters to the saturation control block 336 of the pre-processing module 330 (e.g., to enable the saturation control block 336 to limit the source signal x to within a valid dynamic range). In addition, the system parameters block 348 is configured to provide system parameters to the limit/coefficient generator 346.

The limit/coefficient generator 346 determines appropriate filter coefficients for the dynamic conditioning filter 342 and appropriate delta limits for the delta control block 344. The filter coefficients and the delta limits generated by the limit/coefficient generator 346 can be based on system parameters received from the system parameters block 348, characteristics of the source signal x, characteristics of a filtered signal yf output from the dynamic conditioning filter 342, and/or characteristics of a conditioned signal y output from the delta control block 344.

### 1. Delta Limits

The limit/coefficient generator 346 can determine a delta limit dx_lmt based on both current and power constraints, selecting the more restrictive of the two. For example, delta limits generated by the limit/coefficient generator 346 can be based on system parameters received from the system parameters block 348, characteristics of the source signal x output from the saturation control block 336, and/or characteristics of the conditioned signal y output from the delta control block 344. In particular, current for capacitive loads is proportional to the first derivative of voltage, as shown by Equation 1 below in which C, Fs, and Vf denote a load capacitance, a sample rate, and a full-scale voltage, respectively, provided by the system parameters block 348:

$$I = CdV / dt = CdVFs = FsC ( dxVf ) \qquad Equation 1$$

In Equation 1 above, dx denotes a difference between a sample of the source signal x and a previous sample of the source signal x, as shown by Equation 2 below:

$$dx = \vert x [ n ] - x [ n - 1 ] \vert \qquad Equation 2$$

In some embodiments, the difference dx can be a peak-to-peak difference of the signal content at Nyquist frequency.

Delta limits dxᵢ for given current limits Ix (e.g., received from the system parameters block 348) can therefore be provided by Equation 3 below:

$${dx}_{i} = Ix / ( Fs * C * Vf ) \qquad Equation 3$$

Power P is provided by Equation 4 below in which xr denotes a representative magnitude (0~1) corresponding to a sample of the source signal x output by the saturation control block 336, one or more samples of the conditioned signal y output by the delta control block 344, or a combination thereof:

$$P = IV = CdV / dt * V = FsC ( dxVf ) * ( xrVf ) \qquad Equation 4$$

Delta limits dxₚ for given power limits Px (e.g., received from the system parameters block 348) can therefore be provided by Equation 5 below in which xr is a representative magnitude that represents a magnitude of a worst-case signal between (i) the source signal x output from the saturation control block 336 and (ii) a representative magnitude yr of the conditioned signal y output from the delta control block 344:

$${dx}_{p} = ( \frac{Px}{Fs * C * {Vf}^{2}} ) / xr \qquad Equation 5$$

The representative magnitude xr can be provided by Equation 6 below in which |x[i]| is an instantaneous magnitude of the source signal x and in which yr is a representative magnitude of the conditioned signal y output from the delta control block 344:

$$xr = max ( \vert x [ i ] \vert , y r ) \qquad Equation 6$$

According to Equation 6 above, the representative magnitude xr is the instantaneous magnitude |x[i]| of the source signal x when the instantaneous magnitude |x[i]| is larger than (or equal to) the representative magnitude yr of the conditioned signal y. Otherwise, the representative magnitude yr of the conditioned signal y is used as the representative magnitude xr in Equation 5 above to determine delta limits dxₚ for given power limits Px.

In some embodiments, the representative magnitude yr of the conditioned signal y output from the delta control block 344 can be initially set equal to zero and then updated to be equal to an instantaneous magnitude of a first sample of the conditioned signal y. Thereafter, the representative magnitude yr of the conditioned signal y can be adjusted over time. For example, as the conditioned signal y output from the delta control block 344 changes, the representative magnitude yr can be updated to equal an instantaneous magnitude |y[i]| of the conditioned signal y when the instantaneous magnitude |y[i]| of the conditioned signal y is greater than the current value for the representative magnitude yr of the conditioned signal y (e.g., if yr<|y[i]|, then yr is updated such that yr=|y[i]|). On the other hand, assuming a current value of the representative magnitude yr remains greater than (or equal to) the instantaneous magnitude |y[i]| of the conditioned signal y, the representative magnitude yr of the conditioned signal y can be (a) retained for a preset period of time (or a present number of samples) and then (b) adapted/updated gradually. As a specific example, assuming that a current value for the representative magnitude yr of the conditioned signal y remains greater than (or equal to) the instantaneous magnitude |y[i]| of the conditioned signal y over a prolonged period of time, the representative magnitude yr can be held for a preset period of time tHold (e.g., 1 ms), corresponding to a preset number of samples nHold of the conditioned signal y at a given sample rate (e.g., 48 samples at 48 kHz). Then, the representative magnitude yr can be updated according to Equations 7-10 below such that (a) the representative magnitude yr of the conditioned signal y adapts to a maximum instantaneous magnitude yrl of the source signal y within the preset number of samples nHold, and (b) the representative magnitude yr is adjusted according to a preset time constant Tc (e.g., 1 ms), which corresponds to a preset number of samples nTc at a given sample rate (e.g., 48 samples at 48 kHz):

$$y r 1 = max ( \vert y [ i - nHold ] \vert , … , \vert y [ i ] \vert ) \qquad Equation 7$$

$$a 0 = \frac{n T c}{( n T c + 1 )} \qquad Equation 8$$

$$a 1 = \frac{1}{( n T c + 1 )} \qquad Equation 9$$

$$y r [ i ] = a 0 * y r [ i - 1 ] + a 1 * y r 1 \qquad Equation 10$$

As shown by Equation 11 below, the limit/coefficient generator 346 can be configured to set a delta limit dx_lmt equivalent to a minimum of (i) the delta limit dxᵢ for a given current limit Ix and (ii) the delta limit dxₚ for a given power limit Px:

$$dx\_lmt = min ( {dx}_{i} , {dx}_{p} ) \qquad Equation 11$$

In other embodiments, the limit/coefficient generator 346 can set the delta limit dx_lmt equivalent to either the delta limit per current limit dxᵢ or the delta limit per power limit dxₚ (e.g., not necessarily the minimum of the two).

In some embodiments, the limit/coefficient generator 346 can determine the delta limit dx_lmt using a lookup table (LUT). For example, the limit/coefficient generator 346 can initialize delta limit values dxₚ as a function of the source signal x or as a function of representative magnitude xr, and then determine an appropriate delta limit dx_lmt using a LUT during sample processing.

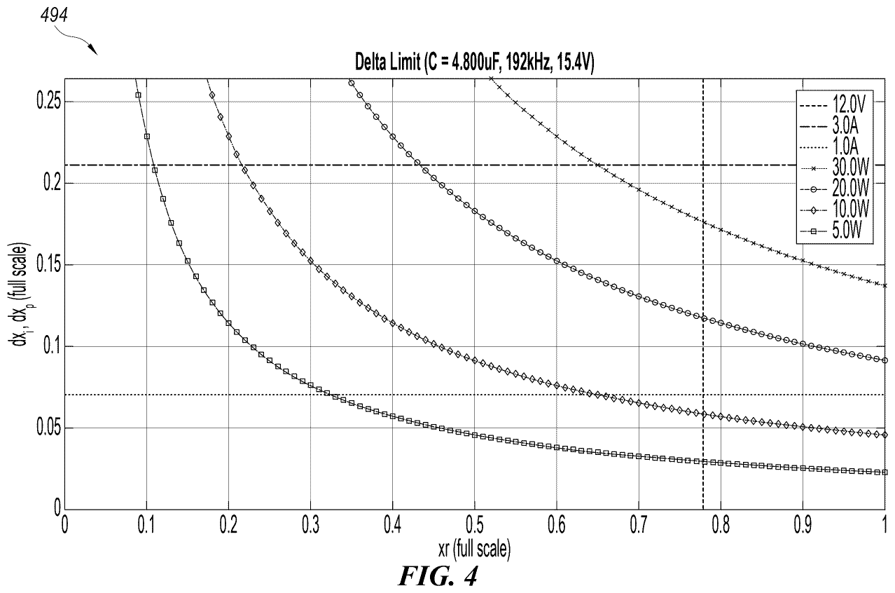

FIG. 4 is a plot 494 showing delta limit curves for different voltage, current, and power (VIP) ratings across a range of representative magnitudes xr in accordance with various embodiments of the present technology. As shown, the x-axis of the plot 494 represents the full-scale representative magnitudes xr from 0 to 1 (which may be instantaneous magnitude of the source signal x or a representative magnitude yr of the conditioned signal y output by the delta limit block 344), while the y-axis represents full-scale delta limit dxᵢ, dxₚ values.

The plot 494 graphs multiple curves corresponding to different voltage, current, and power (VIP) ratings. For example, a vertical dashed line is positioned at approximately 0.779 along the x-axis of the plot 494. This vertical dashed line can correspond to a voltage limit Vx of 12V. More specifically, assuming a voltage limit Vx of 12V and a full-scale voltage Vf of 15.4V, the vertical dashed line on the x-axis of the plot 494 is positioned at the quotient of the voltage limit Vx divided by the full-scale voltage Vf, which corresponds to the voltage limit imposed by the saturation control block 336 of the pre-processing module 330 of FIG. 3 on the upsampled content xu to ensure that the source signal x output from the saturation control block 336 is within a valid dynamic range of the signal conditioning module 340.

The plot 494 further includes two horizontal lines positioned at approximately 0.211 and approximately 0.070 on the y-axis. The horizontal line positioned at approximately 0.211 on the y-axis can correspond to a current limit Ix of 3A, and the horizontal line positioned at approximately 0.070 on the y-axis can correspond to a current limit of 1 A. More specifically, assuming a current limit Ix of 3A, a load capacitance C of 4.8 μF, a sample rate Fs of 192 kHz, and a full-scale voltage Vf of 15.4V, the position of the top horizontal line at approximately 0.211 on the y-axis in the plot 494 of FIG. 4 can be determined using Equation 3 above. Similarly, assuming a current limit Ix of 1A, a load capacitance C of 4.8 μF, a sample rate Fs of 192 kHz, and a full-scale voltage Vf of 15.4V, the position of the top horizontal line at approximately 0.070 on the y-axis in the plot 494 of FIG. 4 can be determined using Equation 3 above. These horizonal lines are referred to herein as current limit curves.

The plot 494 further includes power limit curves that correspond to power limits Px of 30 W, 20 W, 10 W, and 5 W. Each of these curves illustrate how, for the respective power rating, delta limit dxₚ values change with the representative magnitude xr. For example, each of these power limit curves demonstrate that as the representative magnitude xr increases, the corresponding delta limit dxₚ decreases. This relationship reflects the inverse relationship between the representative magnitude xr and allowable change in amplitude (delta) between consecutive samples of the conditioned signal y output from the delta control block 344, to maintain a given power limit. The values of each of the power limit curves shown in FIG. 4 can be determined using Equation 5 above.

As discussed above, the limit/coefficient generator 346 can set the delta limit dx_lmt at any given point in the plot 494 equivalent to the minimum of (a) the delta limit dxᵢ value corresponding to the applicable current limit curve and (b) the delta limit dxₚ corresponding to the applicable power limit curve. For example, at lower representative magnitudes xr, the applicable current limit curve may be the determining factor. Thus, at lower representative magnitudes xr, the limit/coefficient generator 346 may set the delta limit dx_lmt equivalent to the corresponding dxᵢ value. At higher representative magnitudes xr, the applicable power limit curve may intersect with the current limit curve, potentially becoming the determining factor for the delta limit dx_lmt at higher representative magnitudes xr. In other words, the limit/coefficient generator 346 may set the delta limit dx_lmt equivalent to (a) corresponding delta limit dxᵢ values for lower representative magnitudes xr, and (b) corresponding delta limit dxₚ values for higher representative magnitudes xr.

In some embodiments, the limit/coefficient generator 346 may use the plot 494 (or the relationships illustrated in the plot 494) to dynamically adjust the delta limit dx_lmt based on (i) the representative magnitude xr and (ii) the system parameters received from the system parameters block 348. For example, the limit/coefficient generator 346 may calculate the delta limit per current limit dxᵢ based on Equation 3 and the delta limit per power limit dxₚ based on Equation 5, and then select the minimum of these two values as the final delta limit dx_lmt, as shown in Equation 11. In these and other embodiments, the limit/coefficient generator 346 may use the relationships shown in the plot 494 to initialize delta limit dxₚ values as a function of representative magnitude xr, and then use a lookup table (LUT) for determining an appropriate delta limit dx_lmt during sample processing. This approach may allow for efficient real-time adjustment of delta limits based on (i) changing characteristics in the source signal x, (ii) changing characteristics in the conditioned signal y, and/or (iii) system parameters received from the system parameters block 348. As discussed in greater detail below, after the limit/coefficient generator 346 determines an appropriate delta limit dx_lmt, the limit/coefficient generator 346 can provide the delta limit dx_lmt to the delta control block 344, which the delta control block 344 can use to limit a filtered signal yf output from the dynamic conditioning filter 342 relative to a previous sample of the conditioned signal y, as discussed in greater detail below.

The plot 494 of FIG. 4 also illustrates how different system parameters affect the delta limits dxᵢ, dxₚ, and dx_lmt. For example, the plot 494 illustrates that a higher current limit Ix raises the corresponding horizontal current limit curve, potentially allowing for larger delta values dx_lmt across several (e.g., lower) representative magnitudes xr. Similarly, higher power ratings can shift the corresponding power limit curves upward, potentially allowing for larger delta values dx_lmt at several (e.g., higher) representative magnitudes xr.

### 2. Filter Coefficients

As shown in FIG. 3, the dynamic conditioning filter 342 receives and filters the source signal x output by the saturation control block 336 to generate a filtered signal yf based on filter coefficients determined by the limit/coefficient generator 346 of the signal conditioning module 340. In other words, the dynamic conditioning filter 342 transfers the source signal x to a filtered signal yf based on the filter coefficients provided by the limit/coefficient generator 346.

In some embodiments, the dynamic conditioning filter 342 can be a first-order finite-impulse-response (FIR) filter. In these embodiments, the filtered signal yf can be modeled using Equation 12 below:

$$yf [ n ] = B 0 x [ n ] + B 1 x [ n - 1 ] \qquad Equation 12$$

B0 and B1 in Equation 12 above are coefficients that can be determined and provided by the limit/coefficient generator 346 of the signal conditioning module 340.

Equation 13 below models the filtered signal yf provided by the FIR filter in the frequency domain:

$$Yf ( z ) = B 0 * X ( z ) + B 1 * X ( z ) * {z}^{- 1} \qquad Equation 13$$

Thus, the transfer function of the FIR filter is shown by Equation 14 below:

$$H ( z ) = Y ( z ) / X ( z ) = B 0 + B 1 {z}^{- 1} \qquad Equation 14$$

When a difference dx between a sample of the source signal x and a previous sample of the source signal x exceeds the delta limit dx_lmt determined by the limit/coefficient generator 346 (as discussed above), it can be loosely assumed that a desirable gain g at Nyquist frequency (e.g., one-half the sample rate Fs) is given by the following ratio: dx_lmt/dx. Thus, given desired unity gain at DC (z⁻¹=1) and the desired gain g at Nyquist frequency (z⁻¹=−1), we can establish Equation 15 (representing unity gain at DC) and Equation 16 (representing desirable gain g at Nyquist frequency) below to solve for the filter coefficients B0 and B1:

$$B 0 + B 1 = 1 \qquad Equation 15$$

$$B 0 - B 1 = g \qquad Equation 16$$

Solving Equations 15 and 16 simultaneously yields Equations 17 and 18 below that can be used by the limit/coefficient generator 346 to determine and provide the coefficients c (i.e., B0 and B1) to the dynamic conditioning filter 342 for transferring the source signal x to a filtered signal yf:

$$B 0 = ( 1 + g ) / 2 \qquad Equation 17$$

$$B 1 = ( 1 - g ) / 2 \qquad Eqaution 18$$

In some embodiments, the limit/coefficient generator 346 can determine the coefficients B0 and/or B1 using a lookup table (LUT).

The coefficients B0 and B1 ensure that the first-order FIR filter maintains unity gain at DC while achieving the desired gain g at the Nyquist frequency. In addition, by adjusting the gain g based on the ratio of the delta limit dx_lmt to the observed difference dx, the filter can dynamically adapt its frequency response to the characteristics of the source signal x, effectively limiting rapid changes that could lead to excessive currents in the capacitive load. Furthermore, as the delta limit dx_lmt is based on (i) system parameters received from the system parameters block 348, (ii) characteristics of the source signal x output from the saturation control block 336, and (iii) characteristics of the conditioned signal y output from the delta control block 344 (as discussed above and in greater detail below), the filter coefficients for the first-order FIR filter of the dynamic conditioning filter 342 can similarly be based on the system parameters received from the system parameters block 348, characteristics of the source signal x output from the saturation control block 336, and characteristics of the conditioned signal y output from the delta control block 344.

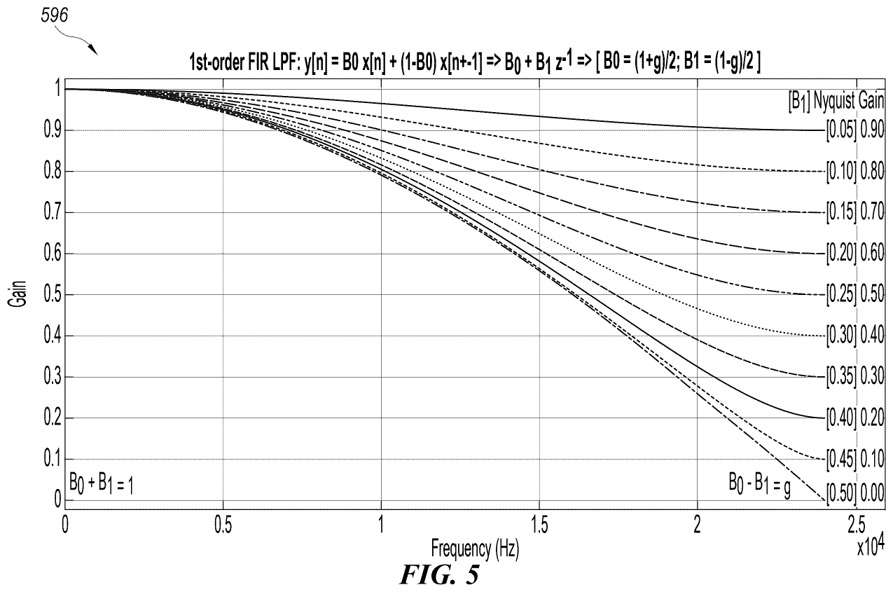

FIG. 5 is a plot 596 illustrating frequency responses of a first-order finite impulse response (FIR) lowpass filter with various sets of coefficients in accordance with several embodiments of the present technology. As discussed above, the dynamic conditioning filter 342 of FIG. 3 may be implemented as a first-order FIR filter in some embodiments. The plot 596 of FIG. 5 demonstrates how the frequency response of the first-order FIR filter changes as the coefficients are adjusted. The x-axis of the plot 596 represents frequency in Hz, while the y-axis represents gain on a linear scale from 0 to 1. Each curve in the plot 596 corresponds to a different set of filter coefficients, illustrating the flexibility of the first-order FIR filter in shaping the frequency response based on the chosen coefficient values.

In some embodiments, the curves in the plot 596 may span a range of gain responses from nearly flat to steep roll-offs at higher frequencies. For example, one curve may represent a filter configuration with coefficients [B0, B1]=[0.95, 0.05], which may result in a relatively flat frequency response. Another curve may represent a filter configuration with coefficients [B0, B1]=[0.50, 0.50], which may result in a more aggressive low-pass filtering effect with a steeper roll-off at higher frequencies.

As discussed above, the limit/coefficient generator 346 of FIG. 3 may dynamically adjust these coefficients based on the characteristics of the source signal x, the characteristics of the conditioned signal y, and the system parameters received from the system parameters block 348. This dynamic adjustment may allow the dynamic conditioning filter 342 to adapt its frequency response in real-time, effectively controlling the signal content at different frequencies to manage current consumption in the capacitive load while maintaining signal fidelity where possible.

In some embodiments, the ability to adjust the filter coefficients may provide a balance between preserving signal content and limiting rapid changes that could lead to excessive currents in the capacitive load. For example, when the signal characteristics indicate a low risk of current overloading, the coefficients may be set to values that result in a flatter frequency response, preserving more of the original signal content. Conversely, when the signal characteristics suggest a higher risk of current overloading, the coefficients may be adjusted to values that result in a more aggressive low-pass filtering effect, attenuating high-frequency components that could lead to rapid current changes.

Referring again to FIG. 3, the dynamic conditioning filter 342 of the signal conditioning module 340 can alternatively be implemented as a first-order infinite-impulse-response (IIR) filter. In these embodiments, the filtered signal yf can be modeled using Equation 19 below:

$$yf [ n ] = B 0 * x [ n ] + A 1 * yf [ n - 1 ] \qquad Equation 19$$

B0 and A1 in Equation 19 above are coefficients that can be determined and provided by the limit/coefficient generator 346 of the signal conditioning module 340.

Equation 20 below models the filtered signal yf provided by the IIR filter in the frequency domain:

$$Yf ( z ) = B 0 * X ( z ) + A 1 * Yf ( z ) * {z}^{- 1} \qquad Equation 20$$

Thus, the transfer function of the IIR filter is shown by Equation 21 below:

$$H ( z ) = B 0 / ( 1 - A 1 * {z}^{- 1} ) \qquad Equation 21$$

Again, when a difference dx between a sample of the source signal x and a previous sample of the source signal x exceeds the delta limit dx_lmt determined by the limit/coefficient generator 346 (as discussed above), it can be loosely assumed that a desirable gain g at Nyquist frequency (e.g., one-half the sample rate Fs) is given by the following ratio: dx_lmt/dx. Thus, given desired unity gain at DC (z⁻¹=1) and the desired gain g at Nyquist frequency (z⁻¹=−1), we can establish Equation 22 (representing unity gain at DC) and Equation 23 (representing desirable gain g at Nyquist frequency) below to solve for the filter coefficients B0 and A1:

$$B 0 + A 1 = 1 \qquad Equation 22$$

$$B 0 = ( 1 + A 1 ) * g \qquad Equation 23$$

Solving Equations 22 and 23 simultaneously yields Equations 24 and 25 below that can be used by the limit/coefficient generator 346 to determine and provide the coefficients c (i.e., B0 and A1) to the dynamic conditioning filter 342 for transferring the source signal x to a filtered signal yf:

$$B 0 = 2 g / ( 1 + g ) \qquad Equation 24$$

$$A 1 = ( 1 - g ) / ( 1 + g ) \qquad Equation 25$$

In some embodiments, the limit/coefficient generator 346 can determine the coefficients B0 and/or A1 using a lookup table (LUT).

The coefficients B0 and A1 ensure that the first-order IIR filter maintains unity gain at DC frequencies while achieving the desired gain g at the Nyquist frequency. In addition, by adjusting the gain g based on the ratio of the delta limit dx_lmt to the observed difference dx, the filter can dynamically adapt its frequency response to the characteristics of the source signal x, effectively limiting rapid changes that could lead to excessive currents in the capacitive load. Furthermore, as the delta limit dx_lmt is based on system parameters received from the system parameters block 348, characteristics of the source signal x output from the saturation control block 336, and characteristics of the conditioned signal y output from the delta control block 344 (as discussed above and in greater detail below), the filter coefficients for the first-order IIR filter of the dynamic conditioning filter 342 can similarly be based on the system parameters received from the system parameters block 348, characteristics of the source signal x output from the saturation control block 336, and characteristics of the conditioned signal y output from the delta control block 344.

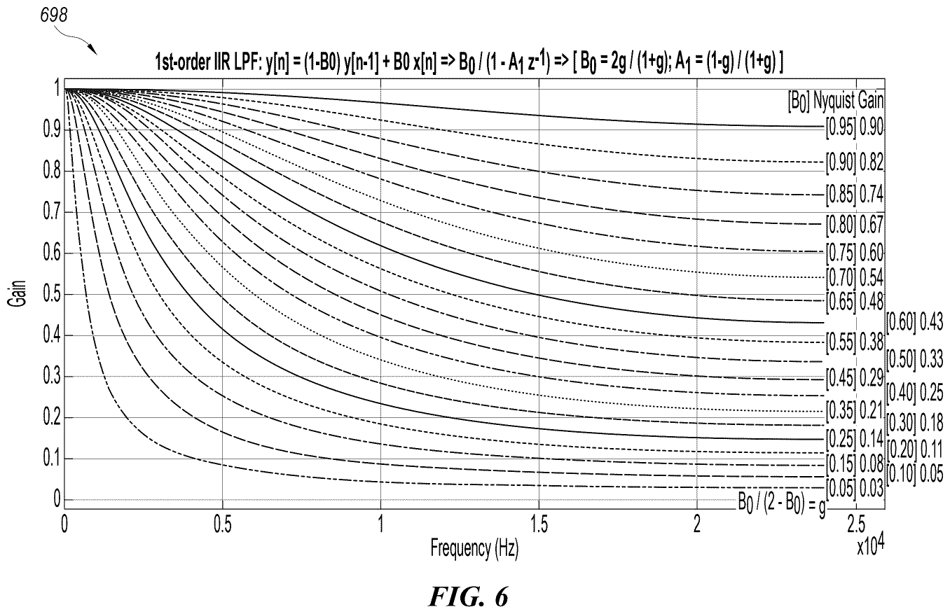

FIG. 6 is a plot 698 illustrating frequency responses of a first-order infinite impulse response (IIR) lowpass filter with various sets of coefficients in accordance with several embodiments of the present technology. As discussed above, the dynamic conditioning filter 342 of FIG. 3 may be implemented as a first-order IIR filter in some embodiments. The plot 698 of FIG. 6 demonstrates how the frequency response of the first-order IIR filter changes as the coefficients are adjusted. The x-axis of the plot 698 represents frequency in Hz, while the y-axis represents gain on a linear scale from 0 to 1. Each curve in the plot 698 corresponds to a different set of filter coefficients, illustrating the flexibility of the first-order IIR filter in shaping the frequency response based on the chosen coefficient values.

In some embodiments, the curves in the plot 698 may span a range of gain responses from nearly flat to steep roll-offs. For example, one curve may represent a filter configuration with coefficients [B0, A1]=[0.95, 0.05], which may result in a relatively flat frequency response. Another curve may represent a filter configuration with coefficients [B0, A1]=[0.10, 0.90], which may result in a more aggressive low-pass filtering effect with a steeper roll-off.

As discussed above, the limit/coefficient generator 346 of FIG. 3 may dynamically adjust these coefficients based on the characteristics of the source signal x, characteristics of the conditioned signal y, and the system parameters received from the system parameters block 348. Such dynamic adjustment may allow the dynamic conditioning filter 342 to adapt its frequency response in real-time, effectively controlling the signal content at different frequencies to manage current consumption in the capacitive load while maintaining signal fidelity where possible.

In some embodiments, the ability to adjust the filter coefficients may provide a balance between preserving signal content and limiting rapid changes that could lead to excessive currents in the capacitive load. For instance, when the signal characteristics indicate a low risk of current overloading, the coefficients may be set to values that result in a flatter frequency response, preserving more of the original signal content. Conversely, when the signal characteristics suggest a higher risk of current overloading, the coefficients may be adjusted to values that result in a more aggressive low-pass filtering effect, attenuating high-frequency components that could lead to rapid current changes.

### 3. Step/Delta Limiter

Referring again to FIG. 3, the filtered signal yf output from the dynamic conditioning filter 342 is fed to the delta control block 344. The delta control block 344 can be a step limiter that is configured to limit the sample-to-sample change in the conditioned signal y based on the delta limit dx_lmt received from the limit/coefficient generator 346 (e.g., to help prevent rapid changes in the conditioned signal y that could lead to excessive currents or voltages in a coupled capacitive load). More specifically, the delta control block 344 is configured to use the delta limit dx_lmt to limit a current sample of the filtered signal yf output from the dynamic conditioning filter 342 relative to a previous (e.g., an immediately previous) sample of the conditioned signal y output from the delta control block 344. In particular, in some embodiments, the delta control block 344 is configured to limit a difference df between (a) a current sample of the filtered signal yf and (b) a last sample of the conditioned signal y (e.g., df=yf[i]−y[i−1]), to ensure the difference remains less than or equal to the delta limit dx_lmt. For example, when the magnitude of the difference df between a current sample of the filtered signal yf[i] and a previous sample of the conditioned signal y[i−1] is less than or equal to the delta limit dx_lmt received from the limit/coefficient generator 346, the delta control block 344 can be configured to pass the sample of the filtered signal yf such that, for example a current sample of the conditioned signal y[i] output from the delta control block 344 is equivalent to the previous sample of the conditioned signal y[i−1] plus the difference df. In other embodiments, when the magnitude of the difference df between a current sample of the filtered signal yf[i] and a previous sample of the conditioned signal y[i−1] is less than or equal to the delta limit dx_lmt received from the limit/coefficient generator 346, the delta control block 344 can be configured to pass the sample of the filtered signal yf with unity gain g (e.g., g=1). On the other hand, when the magnitude of the difference df between a current sample of the filtered signal yf and a previous sample of the conditioned signal y is greater than the delta limit dx_lmt received from the limit/coefficient generator 346, the delta control block 344 can be configured to limit the magnitude of the difference df to the delta limit dx_lmt while retaining the sign s (e.g., positive one (+1) or negative one (−1)) of the difference df such that, for example, a current sample of the conditioned signal y[i] output from the delta control block 344 is equivalent to the previous sample of the conditioned signal y[i−1] plus the product of the sign s of the difference df and the delta limit dx_lmt (e.g., y[i]=y[i−1]+s*dx_lmt). In other embodiments, when the magnitude of the difference df between a sample of the filtered signal yf and a previous sample of the conditioned signal y is greater than the delta limit dx_lmt, the delta control block 344 can be configured to pass the sample of the filtered signal yf with a gain g less than one (e.g., g=dx_lmt/df). The gain g can be a desired gain at Nyquist frequency.

The output of the delta control block 344 is a conditioned signal y that, in some embodiments, can be output from the signal conditioning module 340 of the digital signal processing unit 320 to an amplifier (e.g., the amplifier 250 of FIG. 2) of a corresponding signal driver (e.g., the signal driver 210 of FIG. 2). In turn, as shown in FIG. 2, the output of the amplifier can be provided to an EMI filter (e.g., the EMI filter 260 of FIG. 2) and/or to an emitter (e.g., the emitter 270 of FIG. 2) to emit an associated signal via a capacitive load (e.g., the capacitive load 275 of FIG. 2). As a result, operations performed by the digital signal processing unit 320 of FIG. 3—and particularly by the signal conditioning module 340—can be particularly beneficial when driving capacitive loads such as piezoelectric speakers, which can exhibit challenging impedance characteristics at high frequencies.

### 4. Associated Methods

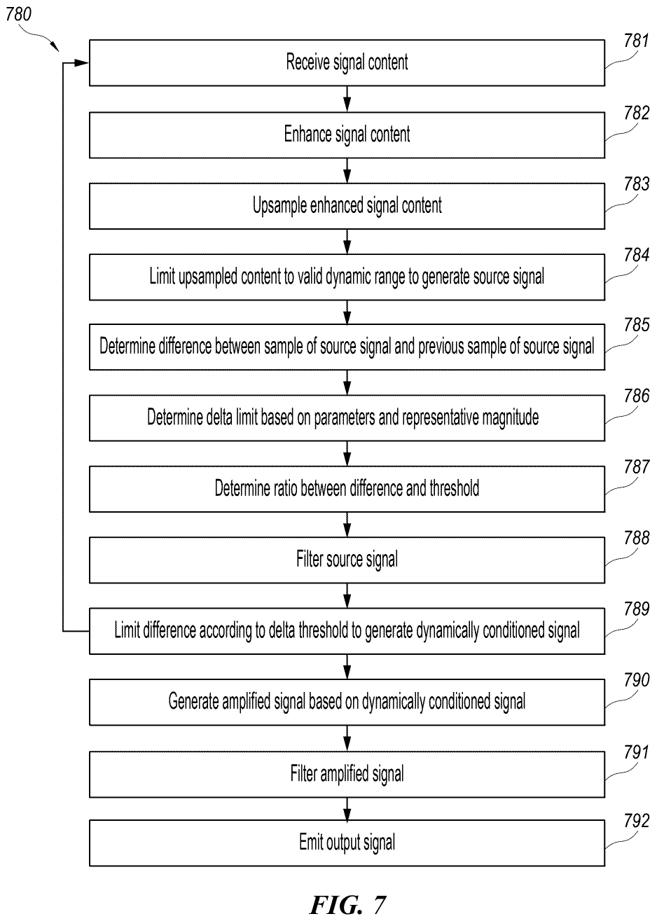

FIG. 7 is a flowchart illustrating a method 780 for processing a signal for emission via a capacitive load in accordance with various embodiments of the present technology. For example, the method 780 may be used for conditioning a signal for emission by a piezo speaker while (a) limiting excessive currents and voltages at higher frequencies and (b) retaining signal fidelity when possible. The method 780 is illustrated as a series of blocks 781-792. All or a subset of one or more of the blocks 781-792 of the method 780 may be executed by various components or devices of a signal emitting system (e.g., the signal emitting system 200 of FIG. 2), such as a digital signal processing unit (e.g., the digital signal processing unit 220 of FIG. 2, the digital signal processing unit 320 of FIG. 3, the pre-processing module 330 of FIG. 3, and/or the signal conditioning module 340 of FIG. 4), an amplifier (e.g., the amplifier 250 of FIG. 2), and EMI filter (e.g., the EMI filter 260 of FIG. 2), and/or an emitter (e.g., the emitter 270 of FIG. 2). Furthermore, all or a subset of any one or more of the blocks 781-792 of the method 780 may be executed in accordance with the discussion above (e.g., with reference to FIGS. 1-6).

The method 780 begins at block 781 by receiving signal content. In some embodiments, the signal content may be audio signals with characteristics similar to those described earlier, such as an audio bandwidth of approximately 60 Hz to 20 kHz and a sample rate of 44.1 kHz or 48 kHz. The signal content may originate from various sources, such as a storage device or a streaming device.

At block 782, the method 780 continues by enhancing the signal content. In some embodiments, enhancement may involve audio processing techniques such as bass boost, equalization (EQ), or other operations to improve the quality or characteristics of the signal content. The specific enhancement techniques applied may vary depending on the desired output characteristics and the nature of the input signal.

At block 783, the method 780 proceeds by upsampling the enhanced signal content. In some embodiments, upsampling may increase the sample rate to at least 128 kHz, which may enable more accurate current estimation in subsequent processing stages. For example, the sample rate may be quadrupled from 48 kHz to 192 kHz. Additionally, or alternatively, the upsampling may ensure that the maximum gradient of the upsampled signal is greater than or equal to that of the original enhanced signal.

At block 784, the method 780 continues by limiting the upsampled content to a valid dynamic range to generate a source signal. In some cases, limiting the upsampled content to the valid dynamic range may be based on system parameters, such as a voltage limit or a full-scale voltage. This step may help address over-voltage conditions while maintaining the fidelity of lower-amplitude signal content.

At block 785, the method 780 proceeds by determining a difference between a sample of the source signal and a previous sample of the source signal. This difference calculation may be crucial for estimating the potential current draw in the capacitive load, as the current in such loads is proportional to the rate of change of voltage. In some embodiments, the difference between a sample of the sample of the source signal and the previous sample of the source signal includes the difference between (a) a sample of the source signal x output from a saturation control block of a pre-processing module of a digital signal processing unit and (b) a previous sample of the source signal x output from the saturation control block. In these and other embodiments, the difference between a sample of the source signal and the previous sample of the source signal includes the difference between (a) a sample of the source signal x output from the saturation control block and (b) a sample of (i) a filtered signal yf output by a dynamic conditioning filter of a signal conditioning module of the digital signal processing unit and corresponding to a previous sample the source signal x or (ii) a conditioned signal y output by a delta control block of the signal conditioning module and corresponding to the previous sample. In these and still other embodiments, the difference between a sample of the source signal and the previous sample of the source signal includes the difference between (a) a sample of the filtered signal yf output by the dynamic conditioning filter and corresponding to a sample of the source signal x output from the saturation control and (b) a sample of (i) the filtered signal yf output by the dynamic conditioning filter and corresponding to a previous sample the source signal x or (ii) a conditioned signal y output by the delta control block and corresponding to the previous sample.

At block 786, the method 780 continues by determining a delta limit (e.g., dx_lmt) based on (i) system parameters and (ii) a representative magnitude. As discussed above, the representative magnitude xr can be a maximum between the instantaneous magnitude |x[i]| of a current sample of the source signal x and a representative magnitude yr of the conditioned signal y. In some embodiments, the delta threshold may be based on both current and power constraints, selecting the more restrictive of the two. The determination may involve calculations using system parameters such as current limits, power limits, load capacitance, and sample rate. The determination may additionally, or alternatively, involve calculations using characteristics of the source signal x and/or characteristics of the conditioned signal y. The delta limit is also referred to herein as a “threshold,” a “delta threshold,” a “delta limit threshold,” and the like.

At block 787, the method 780 proceeds by determining the ratio of the delta limit (determined at block 786) to the difference (calculated at block 785). The ratio may be used to determine a desired gain at Nyquist frequency, which in turn can be used to determine filter coefficients for a dynamic conditioning filter of a signal conditioning module of a digital signal processing unit of a signal driver. In some embodiments, the ratio can be representative of a desired level of signal conditioning to prevent excessive current draw in the capacitive load.

At block 788, the method 780 continues by filtering the source signal. In some cases, the filtering may be performed using a dynamic conditioning filter, which may be implemented as either a first-order finite impulse response (FIR) filter or a first-order infinite impulse response (IIR) filter. As discussed above, the filtering may be performed based at least in part on (a) dynamically adjusted filter coefficients that are determined based on the ratio determined at block 787 and (b) other system parameters.

At block 789, the method 780 proceeds by limiting a sample-to-sample difference between consecutive (e.g., successive, adjacent, immediately adjacent) samples of the conditioned signal y. Limiting the difference between consecutive samples of the conditioned signal according to the delta limit can include producing a dynamically conditioned signal. In some embodiments, limiting the sample-to-sample difference between consecutive samples of the conditioned signal y can include limiting magnitudes of current samples of the filtered signal yf relative to corresponding previous samples of the conditioned signal y and according to the delta limit dx_lmt. For example, limiting the sample-to-sample difference can include (i) determining a difference df between (a) a current sample of the filtered signal yf output by the dynamic conditioning filter and (b) a previous sample (e.g., an immediately previous sample) of the conditioned signal y output from the delta control block. Limiting the sample-to-sample difference can further include comparing a magnitude d of the determined difference df to the corresponding delta limit dx_lmt.

When the magnitude of the determined difference d is less than (or equal to) the corresponding delta limit dx_lmt, limiting the sample-to-sample difference at block 789 can include passing the current sample of the filtered signal yf. For example, when the magnitude d of the determined difference df is less than (or equal to) the corresponding delta limit dx_lmt, limiting the determined difference df according to the delta limit dx_lmt can include passing the current sample of the filtered signal yf with a gain g equivalent to one (1). As another example, when the magnitude d of the determined difference df is less than (or equal to) the corresponding delta limit dx_lmt, limiting the determined difference df according to the corresponding delta limit dx_lmt can include outputting a current sample of the conditioned signal y having a value equivalent to (a) the current sample of the filtered signal yf, (b) the previous sample of the conditioned signal y plus the determined difference df, and/or (c) the previous sample of the conditioned signal y plus the product of a magnitude d of the determined difference df and a sign s of the determined difference df. As a specific example, limiting the sample-to-sample difference at block 789 can include (i) determining a difference df between a current sample yf[i] of the filtered signal yf and a previous sample y[i−1] of the conditioned signal y, (ii) determining a magnitude d and a sign s of the difference df, (iii) comparing the magnitude d to the delta limit dx_lmt, (iv) determining that the magnitude d is less than (or equal to) the delta limit dx_lmt, and/or (v) outputting a current sample y[i] of the conditioned signal y with a value equivalent to the previous sample y[i−1] of the conditioned signal y plus a product of the magnitude d and the sign s.

On the other hand, when the magnitude d of the determined difference df is greater than (or equal to) the corresponding delta limit dx_lmt, limiting the sample-to-sample difference can include limiting a magnitude of the filtered signal yf such that a magnitude of a difference between a previous sample of the conditioned signal y and a current sample of the conditioned signal y is equivalent to the corresponding delta limit dx_lmt. For example, when the magnitude d of the determined difference df is greater than the corresponding delta limit dx_lmt, limiting the determined difference df according to the delta limit dx_lmt can include passing a current sample of the filter signal yf with a gain g equivalent to less than one (1) (e.g., a gain g equivalent to a ratio of the corresponding delta limit dx_lmt to the difference df, or dx_lmt/df). The gain g can be a desired gain at the Nyquist frequency. As another example, when the magnitude d of the determined difference df is greater than (or equal to) the corresponding delta limit dx_lmt, limiting the determined difference df according to the corresponding delta limit dx_lmt can include outputting a current sample of the conditioned signal y having a value equivalent to the previous sample of the conditioned signal y plus the product of the corresponding delta limit dx_lmt and a signs of the determined difference df. As a specific example, limiting the sample-to-sample difference at block 789 can include (i) determining a difference df between a current sample yf[i] of the filtered signal yf and a previous sample y[i−1] of the conditioned signal y, (ii) determining a magnitude d and a sign s of the difference df, (iii) comparing the magnitude d to the delta limit dx_lmt, (iv) determining that the magnitude d is greater than the delta limit dx_lmt, (v) limiting the magnitude d by setting the magnitude d equal to the delta limit dx_lmt, and/or (vi) outputting a current sample y[i] of the conditioned signal y with a value equivalent to the previous sample y|i−1] of the conditioned signal y plus a product of the limited magnitude d and the sign s.

At block 790, the method 780 continues by generating an amplified signal based on the dynamically conditioned signal. In some embodiments, this amplification may be performed by a class D or class AB amplifier with specified voltage, current, and power ratings.

At block 791, the method 780 proceeds by filtering the amplified signal. In some embodiments, the filtering may be performed by an electromagnetic interference (EMI) filter, which may include an LC filter or a ferrite-bead filter designed to reduce unwanted frequencies or noise.

At block 792, the method 780 concludes by emitting an output signal. In some embodiments, the output signal may be emitted by a capacitive load, such as a piezoelectric speaker.

Although the blocks 781-792 of the method 780 are discussed and illustrated in a particular order, the method 780 of FIG. 7 is not so limited. In other embodiments, all or a subset of one or more of the blocks 781-792 of the method 780 may be performed in a different order. In these and other embodiments, all or a subset of any of the blocks 781-792 of the method 780 may be performed before, during, and/or after all or a subset of any of the other blocks 781-792 of the method 780. Furthermore, a person skilled in the art will readily recognize that the method 780 can be altered and still remain within these and other embodiments of the present technology. For example, all or a subset of one or more blocks 781-792 of the method 780 may be omitted and/or repeated in some embodiments. As a specific example, in embodiments in which an EMI filter is omitted, block 791 can be omitted from the method 780.

### 5. Representative Results/Simulations

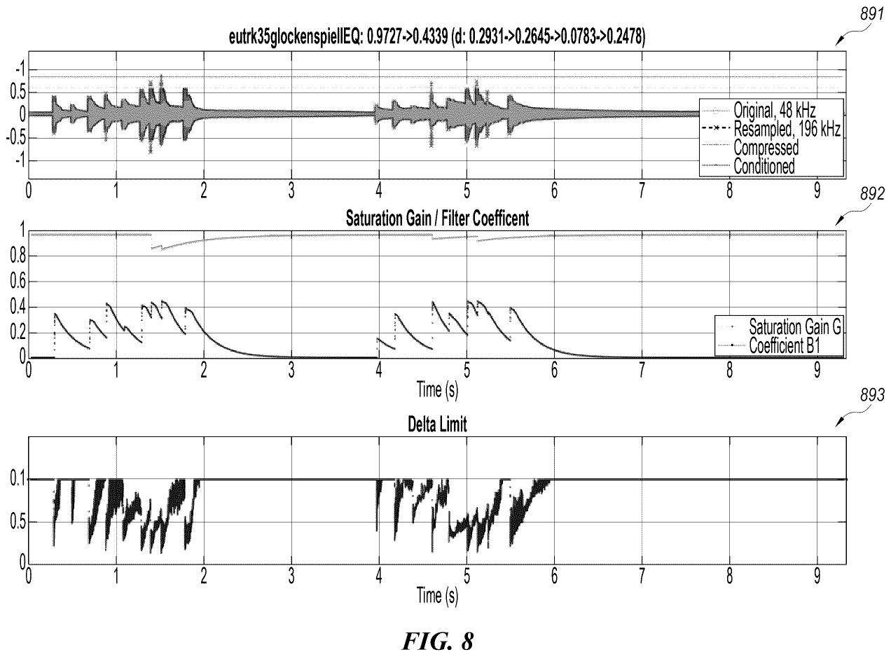

FIG. 8 illustrates a set of three vertically aligned plots 891, 892, and 893 that show different aspects of signal processing for a capacitive load in accordance with various embodiments of the present technology. The plots 891-893 share a common x-axis representing time in seconds.

Plot 891 illustrates amplitude of an audio signal produced using a glockenspiel over time. More specifically, plot 891 illustrates amplitude of an original audio signal sampled at 48 kHz, an upsampled audio signal that is resampled at 196 kHz, a compressed/filtered signal (shown in dark grey) corresponding to the upsampled audio signal, and a conditioned signal (shown in light grey) corresponding to the compressed/filtered signal. The y-axis of plot 891 ranges from −1 to 1, representing the normalized amplitude of the signals. Plot 891 illustrates how the original audio signal is processed and modified throughout different stages of an adaptive current limiting process in accordance with various embodiments of the present technology.

Plot 892 illustrates changes in saturation gain G and in values for a filter coefficient B1 of a finite-impulse-response (FIR) filter over time that are used while processing the audio signal of plot 891 in accordance with various embodiments of the present technology. The y-axis of plot 892 ranges from 0 to 1, with the saturation gain and filter coefficient values fluctuating within this range. Plot 892 shows several distinct periods where the values for the filter coefficient B1 change rapidly, indicating dynamic adjustments in the signal processing to limit current in accordance with the discussion of the present technology above.

Plot 893 depicts changes in delta limit applied to the upsampled audio signal over time by a signal conditioning module configured in accordance with various embodiments of the present technology. The y-axis of plot 893 ranges from 0 to 0.1, representing the magnitude of the delta limit. This plot shows rapid fluctuations in the delta limit, corresponding to the dynamic nature of the signal processing algorithm. As discussed above, the delta limit may be adjusted based on various factors such as signal amplitude, system parameters, and current or power constraints.

Plots 891-893 demonstrate how the disclosed methods can dynamically adjust signal processing parameters to maintain signal fidelity while keeping current consumption within desired limits. The adaptive nature of the disclosed techniques are expected to enable more flexible and efficient signal conditioning, especially when compared to fixed filtering methods.

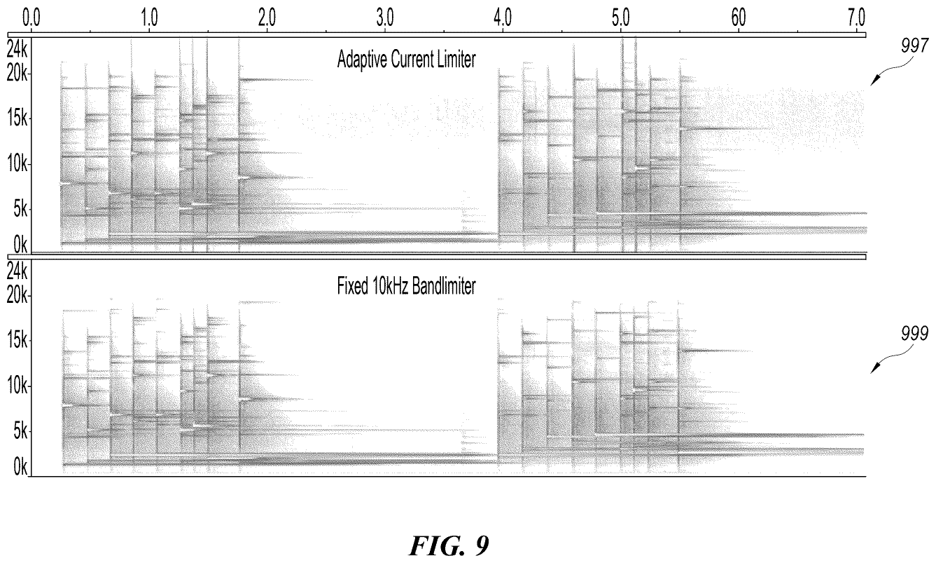

More specifically, FIG. 9 illustrates a comparison of two spectrograms, represented by plots 997 and 999, for two different signal processing methods applied to the same audio signal. The x-axis in both plots represents time from 0.0 to 7.0 seconds, while the y-axis represents frequency from 0 to 24 kHz. The spectrograms use grayscale intensity to represent the signal strength at different frequencies over time.

Plot 997, labeled “Adaptive Current Limiter,” shows a spectrogram of an audio signal processed using an adaptive current limiting technique and/or dynamic conditioning filter in accordance with various embodiments of the present technology. As discussed in greater detail below, plot 997 demonstrates how the adaptive current limiter preserves more of the audio signal's frequency content across time, particularly at higher frequencies.

Plot 999, labeled “Fixed 10 kHz Bandlimiter,” displays a spectrogram of the same audio signal but processed using a fixed bandlimiter, which may represent a conventional low pass filter with a fixed bandwidth. Plot 999 shows a more uniform attenuation of frequencies above 10 kHz across all time periods.

A comparison between plots 997 and 999 illustrates advantages of the adaptive current limiting technique of the present technology over a fixed bandlimiter. In particular, as shown in plot 997, the adaptive current limiter preserves more high-frequency content of the audio signal when possible, resulting in better audio quality. In contrast, as shown in plot 999, the fixed bandlimiter consistently attenuates frequencies above 10 kHz, which results in a noticeable loss in audio quality.

### C. CONCLUSION

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A signal emitting system, comprising:
a signal processing unit configured to:
determine a delta limit based at least in part on (i) a plurality of system parameters and (ii) a representative magnitude corresponding to a sample of a source signal, one or more samples of a conditioned signal output by the signal processing unit, or a combination thereof, wherein the delta limit represents a limit for a first difference between consecutive samples of the conditioned signal,
determine a ratio of (i) the delta limit to (ii) a second difference between the sample of the source signal and a previous sample of the source signal, and
apply a lowpass filter to the source signal to obtain a filtered signal, wherein coefficients of the lowpass filter are based at least in part on the ratio;
an amplifier coupled to an output of the signal processing unit and configured to generate an amplified signal based at least in part on the conditioned signal; and
an emitter configured to emit an output signal based at least in part on the amplified signal.

2. The signal emitting system of claim 1, wherein the signal processing unit is further configured to limit a third difference between a sample of the filtered signal and a previous sample of the conditioned signal according to the delta limit.

3. The signal emitting system of claim 2, wherein, when a magnitude of the third difference is greater than the delta limit, the signal processing unit is configured to generate a sample of the conditioned signal such that a magnitude of a fourth difference between the sample of the conditioned signal and the previous sample of the conditioned signal is less than or equal to the delta limit.

4. The signal emitting system of claim 2, wherein, when a magnitude of the third difference is greater than the delta limit, the signal processing unit is configured to generate a sample of the conditioned signal having a value equivalent to a sum of (a) the previous sample of the conditioned signal and (b) a product of the delta limit and a sign of the third difference.

5. The signal emitting system of claim 2, wherein, when a magnitude of the third difference is less than or equal to the delta limit, the signal processing unit is configured to generate a sample of the conditioned signal having a value equivalent to a sum of (a) the previous sample of the conditioned signal and (b) the third difference.

6. The signal emitting system of claim 2, wherein the representative magnitude is equivalent to a maximum between (a) an instantaneous magnitude of the source signal and (b) a representative magnitude of the conditioned signal.

7. The signal emitting system of claim 6, wherein the representative magnitude of the conditioned signal is equivalent to a maximum between:
an instantaneous magnitude of a current sample of the conditioned signal; and
a magnitude obtained as a function of one or more previous samples of the conditioned signal.

8. The signal emitting system of claim 1, wherein the delta limit is determined as a minimum of a first value and a second value, wherein the first value is equivalent to dx_i=Ix/(Fs*C*Vf), and the second value is equivalent to dx_p=((Px/(Fs*C*Vf²))/xr, where Ix is a current limit, Fs is a sample rate, C is a load capacitance, Vf is a full-scale voltage, Px is a power limit, and xr is the representative magnitude.

9. The signal emitting system of claim 1, wherein the plurality of system parameters include:
a full-scale voltage Vf;
a voltage limit Vx;
a current limit Ix representing a minimum of a current rating of the amplifier, a current rating of any component in series with the emitter, and a saturation current of any component in series with the emitter;
a power limit Px representing a minimum of a power rating of the amplifier and a power rating of the emitter;
a sample rate Fs; and
a load capacitance representing a capacitance of the emitter or a combined capacitance of the emitter and an LC filter coupled between the signal processing unit and the emitter.

10. The signal emitting system of claim 1, wherein the lowpass filter includes a finite-impulse-response (FIR) filter.

11. The signal emitting system of claim 10, wherein the signal processing unit is further configured to dynamically determine coefficients of the FIR filter according to the following equations:
$$B 0 = ( 1 + g ) / 2 , and$$
$$B 1 = ( 1 - g ) / 2 ;$$
and
wherein B0 and B1 are the coefficients of the FIR filter, and g is the ratio.

12. The signal emitting system of claim 1, wherein the lowpass filter includes an infinite-impulse-response (IIR) filter.

13. The signal emitting system of claim 12, wherein the signal processing unit is further configured to dynamically determine coefficients of the IIR filter according to the following equations:
$$B 0 = 2 g / ( 1 + g ) , and$$
$$A 1 = ( 1 - g ) / ( 1 + g ) ;$$
and
wherein B0 and A1 are the coefficients of the IIR filter, and g is the ratio.

14. The signal emitting system of claim 1, wherein the source signal is an audio signal having a sampling rate of at least 128 kHz.

15. The signal emitting system of claim 1, wherein the emitter includes a piezo speaker.

16. The signal emitting system of claim 1, wherein:
the amplifier is a class D amplifier or a class AB amplifier; or
the signal emitting system further comprises an electromagnetic interference (EMI) filter coupled between the amplifier and the emitter.

17. The signal emitting system of claim 1, wherein the signal processing unit is further configured to limit a voltage of the source signal to within a valid dynamic range, the valid dynamic range based at least in part on system parameters including a full-scale voltage and a voltage limit; and wherein the voltage limit represents a minimum of a supply voltage of the amplifier, a voltage rating of a capacitive load of the emitter, and/or a voltage rating of capacitors of an LC filter coupled between the signal processing unit and the emitter.

18. A signal conditioning module for use in a signal emitting system, the signal conditioning module comprising:
a dynamic conditioning filter configured to filter a source signal to generate a filtered signal based at least in part on filter coefficients; and
a limit/coefficient generator configured to:
determine a delta limit based at least in part on (i) a plurality of system parameters and (ii) a representative magnitude corresponding to a sample of the source signal, one or more samples of a conditioned signal output by the signal conditioning module, or a combination thereof, wherein the delta limit represents a limit for a first difference between consecutive samples of the conditioned signal;
determine a ratio of (i) the delta limit to (ii) a second difference between the sample of the source signal and a previous sample of the source signal; and
generate the filter coefficients based at least in part on the ratio.

19. The signal conditioning module of claim 18, further comprising a delta control block configured to limit the first difference by limiting, according to the delta limit, a third difference between a sample of the filtered signal and a previous sample of the conditioned signal.

20. A method of processing a source signal into a conditioned signal for emission of an amplified signal via a capacitive load, the method comprising:
determining a delta limit based at least in part on (i) a plurality of system parameters and (ii) a representative magnitude corresponding to a sample of the source signal, one or more samples of the conditioned signal, or a combination thereof, wherein the delta limit represents a limit for a first difference between two samples of the conditioned signal;
determining a ratio of (i) the delta limit to (ii) a difference between the sample of the source signal and a previous sample of the source signal;
applying a lowpass filter to the source signal to obtain a filtered signal, wherein coefficients of the lowpass filter are based at least in part on the ratio;
generating the conditioned signal based at least in part on the filtered signal; and
generating an amplified signal based at least in part on the conditioned signal for emission via the capacitive load.
